(19) United States
(12) Patent Application Publication
(10) Pub. No.: US 2023/0402530 A1
(43) Pub. Date: Dec. 14, 2023

(54) SEMICONDUCTOR STRUCTURE AND METHOD FOR FORMING SAME

(71) Applicants: Semiconductor Manufacturing International (Shanghai) Corporation, Shanghai (CN); Semiconductor Manufacturing International (Beijing) Corporation, Beijing (CN)

(72) Inventors: Zhenyang ZHAO, Shanghai (CN); Bo SU, Shanghai (CN); Yu FU, Shanghai (CN); Shiliang JI, Shanghai (CN)

(73) Assignees: Semiconductor Manufacturing International (Shanghai) Corporation, Shanghai (CN); Semiconductor Manufacturing International (Beijing) Corporation, Beijing (CN)

(21) Appl. No.: 18/140,030

(22) Filed: Apr. 27, 2023

(30) Foreign Application Priority Data
May 12, 2022 (CN) 202210516017.7

(51) Int. Cl. H01L 29/66; H01L 29/06; H01L 29/417

(52) U.S. Cl. CPC H01L 29/6656; H01L 29/6653; H01L 29/0649; H01L 29/41733; H01L 29/41791; H01L 29/41775; H01L 27/0886

(57) ABSTRACT

Semiconductor structures and methods for forming the same are provided. One form of a method includes: forming a sidewall structure layer on a sidewall of an interconnecting trench, and forming a source/drain interconnecting layer on a sidewall of the sidewall structure layer, filling the interconnecting trench, and in contact with a source/drain doped region, where the sidewall structure layer includes: a sacrificial spacer, arranged on a sidewall of a first spacer and suspended and spaced apart from the source/drain doped region, where along a direction perpendicular to the sidewall of the first spacer, a width of a part of the sacrificial spacer away from the base is greater than a width of a part of the sacrificial spacer close to the base; and a second spacer, filling a gap between a bottom of the sacrificial spacer and the source/drain doped region and arranged between the sacrificial spacer and the source/drain interconnecting layer; removing the sacrificial spacer to form an air gap defined by the second spacer and the first spacer; and forming a sealing layer sealing a top of the air gap, so that the sealing layer, the first spacer, and the second spacer form an air spacer.

### RELATED APPLICATIONS

The present application claims priority to Chinese Patent Appln. No. 202210516017.7, filed May 12, 2022, the entire disclosure of which is hereby incorporated by reference.

### TECHNICAL FIELD

Embodiments and implementations of the present disclosure relate to the field of semiconductor manufacturing, and in particular, to semiconductor structures and methods for forming the same.

### BACKGROUND

With continuous development of integrated circuit manufacturing technologies, people have increasingly high requirements for an integration level and performance of integrated circuits. In order to increase the integration level and reduce costs, critical dimensions of components are continuously decreased, and a circuit density inside integrated circuits becomes increasingly denser. It is becoming increasing challenging for a wafer surface to provide a sufficient area to fabricate a required interconnecting line.

In order to meet requirements of the interconnecting line after the critical dimension is decreased, currently, connection between different metal layers or between a metal layer and a base is achieved using an interconnecting structure. The interconnecting structure includes an interconnecting line and a contact plug formed in a contact opening. The contact plug is connected to a semiconductor device, and the interconnecting line realizes connection between contact plugs, so as to form a circuit.

A contact plug within a transistor structure includes a gate contact plug on a surface of a gate structure and configured to realize connection between the gate structure and an external circuit, and further includes a source/drain contact plug on a surface of a source/drain doped region and configured to realize connection between the source/drain doped region and the external circuit.

However, performance of the current semiconductor structure is still to be improved.

### SUMMARY

To address these problems, embodiments and implementations of the present disclosure provide semiconductor structures and methods for forming the same, so as to increase a process window for forming an air spacer and to improve performance of semiconductor structures.

In one form, the present disclosure provides a semiconductor structure, including: a base; a plurality of gate structures, separately arranged on the base; a first spacer, arranged on a sidewall of each of the gate structures of the plurality of gate structures; a source/drain doped region, arranged within the base on two sides of the gate structures of the plurality of gate structures; a first dielectric layer, arranged on the gate structure and on the base and the source/drain doped region that are located on a side of the first spacer; a source/drain interconnecting layer, extending through the first dielectric layer on a top of the source/drain doped region, where a sidewall of the source/drain interconnecting layer is spaced apart from a sidewall of the first spacer; an air gap, arranged between the first spacer and the source/drain interconnecting layer; a second spacer, arranged on a bottom of the air gap and on the source/drain interconnecting layer exposed from the air gap; and a sealing layer, sealing a top of the air gap, where the sealing layer, the first spacer, and the second spacer form an air spacer, and along a direction perpendicular to the sidewall of the first spacer, a width of a part of the air spacer away from the base is greater than a width of a part of the air spacer close to the base.

In another form, the present disclosure provides a method for forming a semiconductor structure. The method includes: providing a base, where a plurality of separate gate structures are formed on the base, a first spacer is formed on a sidewall of each gate structure of the plurality of gate structures, a source/drain doped region is formed in the base on two sides of the gate structures of the plurality of gate structures, and a first dielectric layer is formed on the gate structures of the plurality of gate structures and on the base and the source/drain doped region on a side of the first spacer; forming an interconnecting trench extending through the first dielectric layer on a top of the source/drain doped region, where a sidewall of the first spacer and the source/drain doped region are exposed from the interconnecting trench; forming a sidewall structure layer on a sidewall of an interconnecting trench, and forming a source/drain interconnecting layer on a sidewall of the sidewall structure layer, filling the interconnecting trench, and in contact with a source/drain doped region, where the sidewall structure layer includes: a sacrificial spacer, arranged on the sidewall of the first spacer and suspended and spaced apart from the source/drain doped region, where along a direction perpendicular to the sidewall of the first spacer, a width of a part of the sacrificial spacer away from the base is greater than a width of a part of the sacrificial spacer close to the base; and a second spacer, filling a gap between a bottom of the sacrificial spacer and the source/drain doped region and arranged between the sacrificial spacer and the source/drain interconnecting layer; removing the sacrificial spacer to form an air gap defined by the second spacer and the first spacer; and forming a sealing layer sealing a top of the air gap, so that the sealing layer, the first spacer, and the second spacer form an air spacer.

Compared with the prior art, the technical solutions of embodiments and implementations of the present disclosure have at least the following advantages:

In the semiconductor structure provided in some forms of the present disclosure, the sealing layer seals a top of the air gap and defines an air spacer with the first spacer and the second spacer. Along the direction perpendicular to the sidewall of the first spacer, a width of a part of the air spacer away from the base is greater than a width of a part of the air spacer close to the base. That is to say, the width of a part of the air spacer close to the top is larger, which helps increase a volume of the air spacer, and also helps increase a proportion of the air spacer between the gate structure and the source/drain interconnecting layer. Accordingly, a parasitic capacitance between the gate structure and the source/drain interconnecting layer is reduced, and the performance of the semiconductor structure is optimized.

In the method for forming a semiconductor structure provided in some forms of the present disclosure, in the step of forming the sidewall structure layer and the source/drain interconnecting layer, along the direction perpendicular to the sidewall of the first spacer, the width of the part of the sacrificial spacer away from the base is greater than the width of the part of the sacrificial spacer close to the base. That is to say, the width of the sacrificial spacer close to the top is larger. Accordingly, in the step of removing the sacrificial spacer to form the air gap, since the width of the sacrificial spacer close to the top is large, an area of the sacrificial spacer exposed from the top is large, which helps reduce the process difficulty of removing the sacrificial spacer and increase the process window for forming the air gap. In addition, the sealing layer sealing the top of the air gap is formed, so that after the sealing layer, the first spacer, and the second spacer define the air spacer, the width of the part of the air spacer away from the base is greater than the width of the part of the air spacer close to the base. That is to say, the width of the air spacer close to a top part is larger, which helps increase a volume of the air spacer, and also helps increase the proportion of the air spacer between the gate structure and the source/drain interconnecting layer. Accordingly, the parasitic capacitance between the gate structure and the source/drain interconnecting layer is further reduced, and the performance of the semiconductor structure is optimized.

### BRIEF DESCRIPTION OF THE DRAWINGS

FIG. 1 to FIG. 6 are schematic structural diagrams corresponding to steps of a method for forming a semiconductor structure.

FIG. 7 is a schematic structural diagram of one form of a semiconductor structure according to the present disclosure.

FIG. 8 to FIG. 21 are schematic structural diagrams corresponding to steps in one form of a method for forming a semiconductor structure according to the present disclosure.

### DETAILED DESCRIPTION

As discussed in the Background, performance of current semiconductor structures needs to be improved. Reasons why the performance of semiconductor structures still needs to be improved are analyzed now in combination with a method for forming a semiconductor structure.

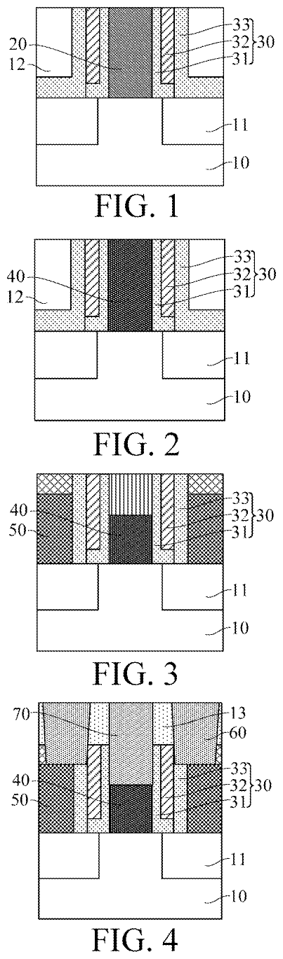

FIG. 1 to FIG. 6 are schematic structural diagrams corresponding to steps of a method for forming a semiconductor structure.

Referring to FIG. 1, a base 10 is provided. A dummy gate structure 20 is formed on the base 10, a source/drain doped region 11 is formed in the base 10 on two sides of the dummy gate structure 20, and a spacer deck 30 is formed on a sidewall of the dummy gate structure 20. The spacer deck 30 includes a first spacer 31. The first spacer 31 includes a first portion on the sidewall of the dummy gate structure 20, and a second portion connected to the first portion and extending onto a part of a top surface of the base 10. The spacer deck 30 further includes a sacrificial spacer 32 on a top of the second portion and a sidewall of the first portion, and a second spacer 33 on a sidewall of the sacrificial spacer 32 and a sidewall of the second portion.

Still referring to FIG. 1, a bottom dielectric layer 12 is formed on the base 10 and the source/drain doped region 11 on sides of the dummy gate structure 20 and the spacer deck 30, and the bottom dielectric layer 12 covers a sidewall of the spacer deck 30.

Referring to FIG. 2, the dummy gate structure 20 is removed, a gate opening (not shown) is formed in the bottom dielectric layer 12, and a gate structure 40 is formed in the gate opening.

Referring to FIG. 3, a source/drain interconnecting layer 50 extending through the bottom dielectric layer 12 and in contact with the source/drain doped region 11 is formed.

Referring to FIG. 4, a sacrificial dielectric layer 13 is formed on the bottom dielectric layer 12, and covers the source/drain contact layer 50, the gate structure 40, and the spacer deck 30. A source/drain plug 60 is formed to extend through the gate structure 40 and the sacrificial dielectric layer 13 and the bottom dielectric layer 12 on two sides of the spacer deck 30 and is in contact with a top of the source/drain contact layer 50. A gate plug 70 is formed to extend through the sacrificial dielectric layer 13 on a top of the gate structure 40 and to be in contact with the gate structure 40.

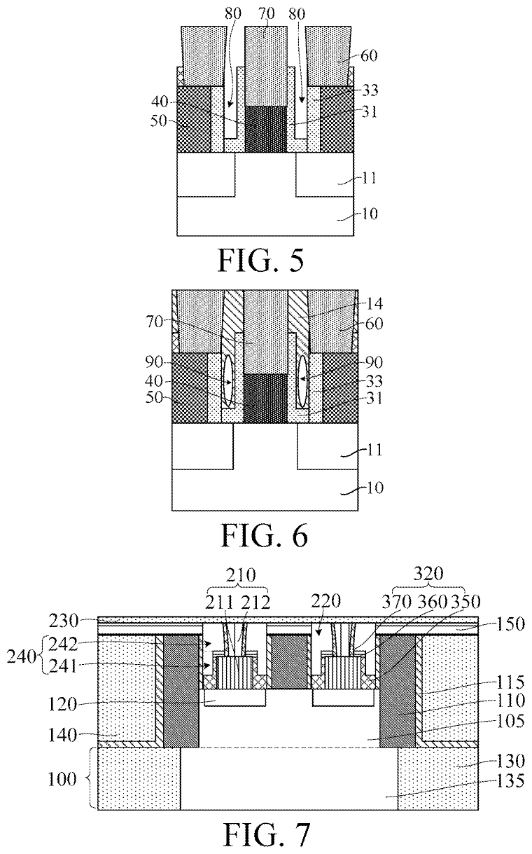

Referring to FIG. 5, after the source/drain plug 60 and the gate plug 70 are formed, the sacrificial dielectric layer 13 and the sacrificial spacer 32 are removed, so that the first spacer 31 and the second spacer 33 define a gap 80.

Referring to FIG. 6, a top dielectric layer 14 between the source/drain plug 60 and the gate plug 70 is formed on the bottom dielectric layer 12, and the top dielectric layer 14 seals a top of the gap 80 to form an air gap 90.

In the foregoing forming method, after the source/drain plug 60 and the gate plug 70 are formed, the sacrificial dielectric layer 13 and the sacrificial spacer 32 are removed. A height difference between a top surface of the source/drain plug 60 and a top surface of the second spacer 33 is large, and a depth-to-width ratio of the gap is large, resulting in a small process window for the sacrificial dielectric layer 13 and the sacrificial spacer 32 to be removed, and a great process difficulty. Therefore, the method is not suitable for mass production.

To address this technical problem, embodiments and implementations of the present disclosure provides a semiconductor structure. A width of a part of the air spacer away from the base is greater than a width of a part of the air spacer close to the base. That is to say, the width of the air spacer close to a top part is larger, which helps increase a volume of the air spacer, and also helps increase a proportion of the air spacer between the gate structure and the source/drain interconnecting layer. Accordingly, a parasitic capacitance between the gate structure and the source/drain interconnecting layer is reduced.

To make the foregoing objectives, features, and advantages of embodiments and implementations of the present disclosure more apparent and easier to understand, specific embodiments and implementations of the present disclosure are described in detail below with reference to the accompanying drawings. Referring to FIG. 7, a schematic structural diagram of one form of a semiconductor structure according to the present disclosure is shown.

In this form, the semiconductor structure includes: a base 100; a plurality of gate structures 110, separately arranged on the base 100; a first spacer, arranged on a sidewall of each of the gate structures 110; a source/drain doped region 120, arranged within the base 100 on two sides of the gate structure 110; a first dielectric layer 140, arranged on the gate structure 110 and on the base 100 and the source/drain doped region 120 that are located on a side of the first spacer; a source/drain interconnecting layer 210, extending through the first dielectric layer 140 on a top of the source/drain doped region 120, where a sidewall of the source/drain interconnecting layer 210 is spaced apart from a sidewall of the first spacer; an air gap 220 (refer to FIG. 20), arranged between the first spacer and the source/drain interconnecting layer 210; a second spacer 320, arranged on a bottom of the air gap 220 and the source/drain interconnecting layer 210 exposed from the air gap 220; and a sealing layer 230, sealing a top of the air gap, where the sealing layer, the first spacer, and the second spacer 320 define an air spacer 240, and along a direction perpendicular to the sidewall of the first spacer, a width of a part of the air spacer 240 away from the base 100 is greater than a width of a part of the air spacer close to the base 100.

The base 100 is configured to provide a process platform for the formation process of the semiconductor structure. In some implementations, the base 100 is a three-dimensional base. In other implementations, the base may further be a planar base.

In some implementations, the base 100 includes a substrate (not shown), a protrusion 135 separately arranged on the substrate, and a channel structure layer 105 arranged on the protrusion 135.

In some implementations, the substrate is a silicon substrate. In other implementations, a material of the substrate may further be other materials such as germanium, silicon germanium, silicon carbide, gallium arsenide, indium gallium, or the like. The substrate may further be other types of substrates such as a silicon substrate on an insulator or a germanium substrate on the insulator. The material of the substrate may be a material suitable for process requirements or easy integration.

The protrusion 135 is configured to provide a support for the channel structure layer. In some implementations, a material of the protrusion 135 is silicon. In other implementations, a material of the protrusion may further be other materials such as germanium, silicon germanium, silicon carbide, gallium arsenide, or indium gallium.

The channel structure layer 105 is configured to provide a conductive channel of a field effect transistor. In some implementations, a material of the channel structure layer 105 is the same as the material of the substrate, and the material of the channel structure layer 105 is silicon. In other implementations, the material of the channel structure layer may further be a semiconductor material suitable for forming a channel structure layer, such as germanium, silicon germanium, silicon carbide, gallium arsenide, or indium gallium.

In some implementations, the base 100 configured to from a fin field effect transistor (FinFET) is used as an example. The channel structure layer 105 is a fin. The fin is configured to provide a conductive channel of the FinFET. In some implementations, the fin and the protrusion 135 are integrally formed.

In other implementations, during formation of a gate-all-around transistor, the channel structure layer is suspended on the protrusion, and the channel structure layer includes one or more channel layers suspended at intervals. The channel layer is configured to provide a conductive channel of the gate-all-around transistor.

In some implementations, the semiconductor structure further includes an isolation layer 130 arranged on the substrate, surrounding the protrusion 135, and exposing the channel structure layer 105. The gate structure 110 is arranged on the isolation layer 130. The isolation layer 130 is configured to isolate adjacent protrusions 135 and further configured to isolate the substrate from the gate structure 110. In some implementations, a material of the isolation layer 130 includes one or more of silicon oxide, silicon oxynitride, or silicon nitride.

The gate structure 110 is configured to control opening and closing of the conductive channel of the field effect transistor. In some implementations, the gate structure 110 is arranged on the isolation layer 130 and spans the channel structure layer 105.

Specifically, In some implementations, the gate structure 110 is arranged on the isolation layer 130, and the gate structure 110 spans the fin and covers a part of a top and a part of a sidewall of the fin. In other implementations, when the channel structure layer includes one or more channel layers suspended at intervals, the gate structure is arranged on the isolation layer and surrounds the channel layer.

In some implementations, the gate structure 110 is a metal gate structure.

The first spacer is configured to protect a sidewall of the gate structure 110. The first spacer may be a single-layer or deck structure. As an example, a material of the first spacer includes one or more of silicon oxide, a low-k dielectric material, or an ultra-low-k dielectric material.

In some implementations, the first spacer includes: a gate spacer (not shown), arranged on a sidewall of the gate structure 110; and a contact etching barrier layer 115, arranged on the sidewall of the gate spacer. The contact etching barrier layer 115 is further arranged between the isolation layer 130 and the first dielectric layer 140.

The gate spacer is configured to define a position at which the source/drain doped region 120 is formed. As an example, a material of the gate spacer includes one or more of silicon oxide, a low-k dielectric material, or an ultra-low-k dielectric material.

The contact etching barrier layer 115 is configured to temporarily define an etching stop position in the step of forming the interconnecting trench, so as to reduce a probability that the etching process of forming the interconnecting trench causes damage to the source/drain doped region 120. The contact etching barrier layer 115 on the sidewall of the gate spacer also protects the sidewall of the gate structure 110.

As an example, a material of the contact etching barrier layer 115 is silicon nitride.

The source/drain doped region 120 is configured as a source region or a drain region of a transistor, and is configured to provide a carrier source when a device operates. In some implementations, the source/drain doped region 120 is arranged in the fins on two sides of the gate structure 110.

In some implementations, the source/drain doped region 120 includes a stress layer doped with ions. When an NMOS transistor is formed, a material of the stress layer is Si or SiC, and the stress layer is doped with N-type ions. When a PMOS transistor is formed, the material of the stress layer is Si or SiGe, and the stress layer is doped with P-type ions.

The first dielectric layer 140 is configured to isolate adjacent gate structures 110. In some implementations, the first dielectric layer 140 is arranged on the gate structure 110 and the isolation layer 130 and the source/drain doped region 120 that are located on a side of the first spacer. Specifically, the first dielectric layer 140 is arranged on the contact etching barrier layer 115.

The first dielectric layer 140 is an interlayer dielectric layer. A material of the first dielectric layer 140 is an insulating material, including one or more of silicon oxide, silicon nitride, silicon oxynitride, silicon oxycarbide, silicon carbonitride, or silicon oxycarbonitride. As an example, the material of the first dielectric layer 140 is silicon oxide.

The source/drain interconnecting layer 210 is in contact with the source/drain doped region 120 to realize an electrical connection between the source/drain doped region 120 and an external circuit or other interconnecting structures. The sidewall of the source/drain interconnecting layer 210 is spaced apart from the sidewall of the first spacer, so that the air gap is formed between the source/drain interconnecting layer 210 and the first spacer.

As an example, a material of the source/drain interconnecting layer 210 is copper. A relatively low resistivity of copper helps improve a signal delay of a back end of line RC and increase a processing speed of a chip, and also helps reduce a resistance of the source/drain interconnecting layer 210, thereby reducing power consumption accordingly. In other implementations, the material of the source/drain interconnecting layer may further be a conductive material such as tungsten or cobalt.

In some implementations, the source/drain interconnecting layer 210 includes a bottom interconnecting layer 211 and a top interconnecting layer 212 on the bottom interconnecting layer 211. Along a direction perpendicular to an extending direction of the gate structure 110, a sidewall of the top interconnecting layer 212 is retracted relative to a sidewall of the bottom interconnecting layer 211 on a same side.

Along a direction perpendicular to the extending direction of the gate structure 110, the sidewall of the top interconnecting layer 212 is retracted relative to the sidewall of the bottom interconnecting layer 211 on a same side. Therefore, compared with an interval between the sidewall of the bottom interconnecting layer 211 and the sidewall of the adjacent first spacer, an interval between the sidewall of the top interconnecting layer 212 and the sidewall of the adjacent first spacer is larger, which is beneficial to cause a size of a part of the air gap 220 close to the top to be larger.

The air gap 220 is configured to be sealed by the sealing layer 230 to form an air spacer 240. In some implementations, the air spacer 240 includes a first portion 241 and a second portion 242 on the first portion 241. A width of the second portion 242 is greater than a width of the first portion 241.

The second spacer 320 is configured to define the air spacer 240 with the first spacer and the sealing layer 230. In addition, during formation of the semiconductor structure, the air gap 220 is formed by removing the sacrificial spacer, and the second spacer 320 is further configured to protect the source/drain doped region 120 during removal of a sacrificial spacer 310 (as shown in FIG. 17).

In some implementations, a material of the second spacer 320 includes one or more of silicon oxide, a low-k dielectric material, or an ultra-low-k dielectric material. The material of the second spacer 320 has a small dielectric constant, which is beneficial to further reduce parasitic capacitance between the gate structure 110 and the source/drain interconnecting layer.

It should be noted that a thickness of the second spacer 320 on a bottom of the air gap 220 should be neither excessively small nor excessively large. Since the air gap 220 is formed by removing the sacrificial spacer during the formation of the semiconductor structure, the probability that the second spacer 320 on the bottom of the air gap 220 is completely consumed is easily increased if the thickness of the second spacer 320 on the bottom of the air gap 220 is excessively small. If the thickness of the second spacer 320 on the bottom of the air gap 220 is excessively large, a volume of the air gap 220 easily become smaller. Therefore, In some implementations, the thickness of the second spacer 320 on the bottom of the air gap 220 ranges from 0.5 nm to 2 nm.

As an example, the second spacer 320 includes: a first spacer material layer 350, arranged on a bottom of the first portion 241 and on the bottom interconnecting layer 211 exposed from the first portion 241; a second spacer material layer 360, arranged on a top surface of the bottom interconnecting layer 211 exposed from the second portion 242 and covering a top of the first spacer material layer 350; and a third spacer material layer 370, arranged on a sidewall of the top interconnecting layer 212 exposed from the second portion 242 and connected to the second spacer material layer 360.

In some implementations, the first spacer material layer 350, the second spacer material layer 360, and the third spacer material layer 370 are made of a same material, which can help improve process compatibility. In other implementations, the first spacer material layer, the second spacer material layer, and the third spacer material layer made further be made of different materials.

In some implementations, the second spacer 320 is a multi-layer structure by way of example for description. In other implementations, the second spacer may further be integrally formed, so as to further increase the density of the second spacer and improve the sealing effect on the air gap.

The sealing layer 230 is configured to define the air spacer 240 with the first spacer and the second spacer 320. The air spacer 240 is arranged between the source/drain interconnecting layer 210 and the gate structure 110, and a dielectric constant of the air spacer 240 is lower than a dielectric constant of a common dielectric material in the field of semiconductors, which is beneficial to reduce the parasitic capacitance between the gate structure 110 and the source/drain interconnecting layer 210.

In some implementations, the width of the part of the air spacer 240 close to the top is larger, which is beneficial to increase a volume of the air spacer 240, and further beneficial to increase a proportion of the air spacer 240 between the gate structure 110 and the source/drain interconnecting layer 210. Accordingly, the parasitic capacitance between the gate structure 110 and the source/drain interconnecting layer 210 is further reduced, and the performance of the semiconductor structure is optimized.

In some implementations, a material of the sealing layer 230 includes one or more of silicon oxide, silicon nitride, a low-k dielectric material, or an ultra-low-k dielectric material.

In some implementations, the sealing layer 230 is arranged on the first dielectric layer 140 and the gate structure 110, and seals a top of the air gap 220. The semiconductor structure further includes a planarization stop layer 150 arranged between the first dielectric layer 140 and the sealing layer 230 and between the top of the gate structure 110 and the sealing layer 230.

The planarization stop layer 150 is configured to define a stop position in the planarization process in the step of forming the source/drain interconnecting layer 210, thereby improving top flatness and height uniformity of the source/drain interconnecting layer 210. In some implementations, a material of the planarization stop layer 150 is silicon nitride. In other implementations, the planarization stop layer may further be omitted in the semiconductor structure.

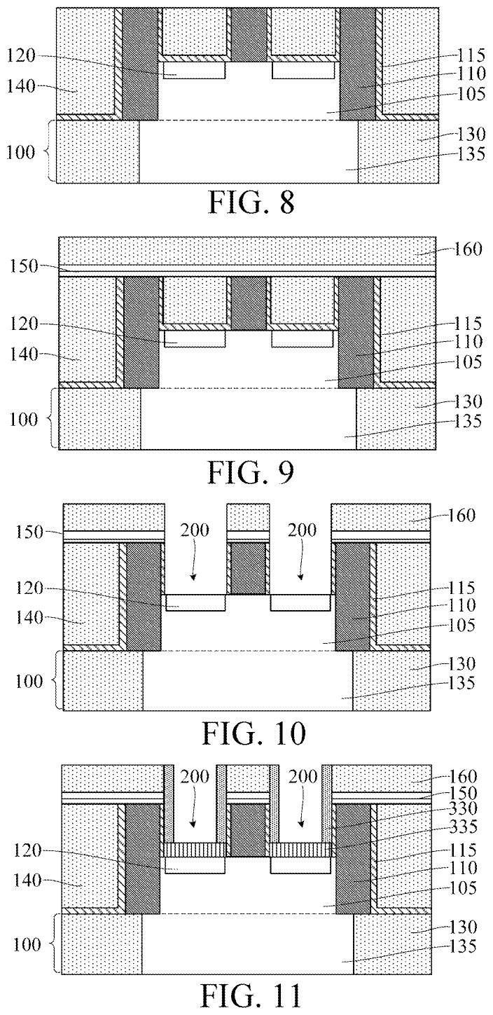

The present disclosure further provides methods for forming a semiconductor structure. FIG. 8 to FIG. 21 are schematic structural diagrams corresponding to steps in one form of a method for forming a semiconductor structure according to the present disclosure.

Referring to FIG. 8, a base 100 is provided. A plurality of separate gate structures 110 are formed on the base 100. A first spacer is formed on a sidewall of each gate structure 110. A source/drain doped region 120 is formed in the base 100 on two sides of the gate structure 110, and a first dielectric layer 140 is formed on the gate structure 110 and on the base 100 and the source/drain doped region 120 that are located on a side of the first spacer.

The base 100 is configured to provide a process platform for the subsequent process. In some implementations, the base 100 is a three-dimensional base. In other implementations, the base may further be a planar base.

In some implementations, the base 100 includes a substrate (not shown), a protrusion 135 separately arranged on the substrate, and a channel structure layer 105 arranged on the protrusion 135. In some implementations, the substrate is a silicon substrate.

The protrusion 135 is configured to provide a support for the channel structure layer. In some implementations, the protrusion 135 and the substrate are integrally formed. In some implementations, a material of the protrusion 135 is silicon.

The channel structure layer 105 is configured to provide a conductive channel of a field effect transistor. In some implementations, a material of the channel structure layer 105 is the same as the material of the substrate, and the material of the channel structure layer 105 is silicon. In other implementations, the material of the channel structure layer may further be a semiconductor material suitable for forming a channel structure layer, such as germanium, silicon germanium, silicon carbide, gallium arsenide, or indium gallium.

In some implementations, a FinFET is formed, and the channel structure layer 105 is a fin. In some implementations, the fin and the protrusion 135 are integrally formed. In other implementations, when the base is configured to form a gate-all-around transistor, the channel structure layer is suspended on the protrusion, and the channel structure layer includes one or more channel layers suspended at intervals. The channel layer is configured to provide a conductive channel of the gate-all-around transistor.

In some implementations, an isolation layer 130 surrounding the protrusion 135 and exposing the channel structure layer 105 is further formed on the substrate. The gate structure 110 is arranged on the isolation layer 130. The isolation layer 130 is configured to isolate adjacent protrusions 135 and further configured to isolate the substrate from the gate structure 110. In some implementations, a material of the isolation layer 130 includes one or more of silicon oxide, silicon oxynitride, or silicon nitride.

The gate structure 110 is configured to control opening and closing of the conductive channel of the field effect transistor. In some implementations, the gate structure 110 is arranged on the isolation layer 130 and spans the channel structure layer 105. Specifically, in some implementations, the gate structure 110 is arranged on the isolation layer 130, and the gate structure 110 spans the fin and covers a part of a top and a part of a sidewall of the fin. In other implementations, when the channel structure layer includes one or more channel layers suspended at intervals, the gate structure is arranged on the isolation layer and surrounds the channel layer.

In some implementations, the gate structure 110 is a metal gate structure, and the gate structure 110 is formed by using a high-k last metal gate last process.

The first spacer is configured to protect a sidewall of the gate structure 110. The first spacer may be a single-layer or deck structure. As an example, a material of the first spacer includes one or more of silicon oxide, a low-k dielectric material, or an ultra-low-k dielectric material.

In some implementations, a gate spacer (not shown) and a contact etching barrier layer 115 on a sidewall of the gate spacer are formed on the sidewall of the gate structure 110. The contact etching barrier layer 115 is further arranged between the source/drain doped region 120 and the first dielectric layer 140, and the gate spacer and the contact etching barrier layer 115 on the sidewall of the gate structure 110 are configured to form the first spacer.

The gate spacer is configured to define a position at which the source/drain doped region 120 is formed. As an example, a material of the gate spacer includes one or more of silicon oxide, a low-k dielectric material, or an ultra-low-k dielectric material.

The contact etching barrier layer 115 is configured to temporarily define an etching stop position in the step of subsequently forming the interconnecting trench, so as to reduce a probability that the etching process of forming the interconnecting trench causes damage to the source/drain doped region 120. As an example, a material of the contact etching barrier layer 115 is silicon nitride.

The source/drain doped region 120 is configured as a source region or a drain region of a transistor, and is configured to provide a carrier source when a device operates. In some implementations, the source/drain doped region 120 is arranged in the fins on two sides of the gate structure 110.

In some implementations, the source/drain doped region 120 includes a stress layer doped with ions. When an NMOS transistor is formed, a material of the stress layer is Si or SiC, and the stress layer is doped with N-type ions. When a PMOS transistor is formed, the material of the stress layer is Si or SiGe, and the stress layer is doped with P-type ions.

The first dielectric layer 140 is configured to isolate adjacent gate structures. In some implementations, the first dielectric layer 140 is arranged on the gate structure 110 and the isolation layer 130 and the source/drain doped region 120 that are located on a side of the first spacer. Specifically, the first dielectric layer 140 is arranged on the contact etching barrier layer 115.

The first dielectric layer 140 is an interlayer dielectric layer. A material of the first dielectric layer 140 is an insulating material, including one or more of silicon oxide, silicon nitride, silicon oxynitride, silicon oxycarbide, silicon carbonitride, or silicon oxycarbonitride. As an example, the material of the first dielectric layer 140 is silicon oxide.

Referring to FIG. 9, after providing the base 100, the forming method further includes: forming a planarization stop layer 150 on the first dielectric layer 140; and forming a second dielectric layer 160 on the planarization stop layer 150.

By forming the planarization stop layer 150 and the second dielectric layer 160, there is an etching selection ratio between the second dielectric layer and the planarization stop layer 150. Therefore, after a sidewall structure layer and the source/drain interconnecting layer are subsequently formed, the source/drain interconnecting layer and the second dielectric layer can be planarized with the top surface of the planarization stop layer as the stop position, thereby improving top flatness and height uniformity of the source/drain interconnecting layer.

There is an etch selectivity between a material of the planarization stop layer 150 and a material of the second dielectric layer 160, so that the subsequent planarization process of the top conductive material and the second dielectric layer 160 can stop on the planarization stop layer 150.

In some implementations, the material of the planarization stop layer 150 is silicon nitride. In some implementations, the material of the second dielectric layer 160 is silicon oxide.

Referring to FIG. 10, an interconnecting trench 200 extending through the first dielectric layer 140 on a top of the source/drain doped region 120 is formed. A sidewall of the first spacer and the source/drain doped region 120 are exposed from the interconnecting trench 200.

The interconnecting trench 200 is configured to provide a spatial position for subsequently forming the source/drain interconnecting layer. The source/drain doped region 120 is exposed from the interconnecting trench 200, so that the source/drain interconnecting layer can contact the source/drain doped region 120 subsequently.

In some implementations, the interconnecting trench 200 extends through the contact etching barrier layer 115, the first dielectric layer 140, the planarization stop layer 150, and the second dielectric layer 160 on the top of the source/drain doped region 120.

In some implementations, the second dielectric layer 160, the planarization stop layer 150, the first dielectric layer 140, and the contact etching barrier layer 115 above the top of the source/drain doped region 120 are sequentially etched using an anisotropic dry etching process. The contact etching barrier layer 115 can temporarily etch the stop position of the process, thereby reducing the probability of damage to the source/drain doped region 120 caused by the etching process.

Referring to FIG. 11 to FIG. 18, a sidewall structure layer 300 on a sidewall of the interconnecting trench 200, and a source/drain interconnecting layer 210 on a sidewall of the sidewall structure layer 300, filling the interconnecting trench 200, and in contact with the source/drain doped region 120 are formed. The sidewall structure layer 300 includes: a sacrificial spacer 310, arranged on the sidewall of the first spacer and suspended and spaced apart from the source/drain doped region 120, where along a direction perpendicular to the sidewall of the first spacer, a width of a part of the sacrificial spacer 310 away from the base 100 is greater than a width of a part of the sacrificial spacer close to the base 100; and a second spacer 320, filling a gap between a bottom of the sacrificial spacer 310 and the source/drain doped region 120, and arranged between the sacrificial spacer 310 and the source/drain interconnecting layer 210.

The sidewall structure layer 300 is configured to subsequently form an air gap. The sacrificial spacer 310 is configured to provide a spatial position for forming the air gap.

Along the direction perpendicular to the sidewall of the first spacer, the width of the part of the sacrificial spacer 310 away from the base 100 is greater than the width of the part of the sacrificial spacer close to the base 100. That is to say, the width of the part of the sacrificial spacer 310 close to the top is larger. Accordingly, in the subsequent step of removing the sacrificial spacer 310 to form the air gap, since the width of a part of the sacrificial spacer 310 close to the top is larger, an area exposed from the top of the sacrificial spacer 310 is relatively large, which is beneficial to reduce the process difficulty of removing the sacrificial spacer 310 and increase the process window for forming the air gap.

In addition, in the subsequent formation of the sealing layer sealing the top of the air gap, after the sealing layer, the first spacer, and the second spacer 320 define the air spacer, the width of the part of the air spacer close to the top is larger, which is beneficial to increase a volume of the air spacer, and further beneficial to increase the proportion of the air spacer between the gate structure 110 and the source/drain interconnecting layer 210. Accordingly, the parasitic capacitance between the gate structure 110 and the source/drain interconnecting layer 210 is further reduced, and the performance of the semiconductor structure is optimized.

In some implementations, the sacrificial spacer 310 includes a first sacrificial portion 311 and a second sacrificial portion 312 on the first sacrificial portion 311. Along a direction perpendicular to the sidewall of the first spacer, a width of the second sacrificial portion 312 is greater than a width of the first sacrificial portion 312, such that the width of the part of the sacrificial spacer 310 away from the base 100 is greater than the width of the part of the sacrificial spacer close to the base 100.

A bottom of the first sacrificial portion 311 is suspended and spaced apart from the source/drain doped region 120, so that the second spacer 320 can be arranged between the bottom of the first sacrificial portion 311 and the source/drain doped region. Correspondingly, in the subsequent process of removing the sacrificial spacer 311 to form the air gap, the probability that the process of removing the sacrificial spacer 311 causes damage to the source/drain doped region 120 can be reduced.

The sacrificial spacer 310 is made of a material that is easily removed, so as to reduce the process difficulty of subsequently removing the sacrificial spacer 310. As an example, a material of the sacrificial spacer 310 includes one or more of amorphous silicon, silicon oxycarbide, silicon oxide, silicon nitride, silicon carbide, boron nitride, aluminum oxide, aluminum nitride, or silicon oxynitride.

In some implementations, the first sacrificial portion 311 and the second sacrificial portion 312 are made of a same material, so that the first sacrificial portion 311 and the second sacrificial portion 312 can be easily removed by using a same etching step, which is beneficial to improve the process compatibility. In some implementations, the first sacrificial portion 311 and the second sacrificial portion 312 are made of amorphous silicon.

In other implementations, the first sacrificial portion and the second sacrificial portion may further be made of different materials.

The second spacer 320 is configured to subsequently define the air gap with the first spacer, and is further configured to protect the source/drain doped region 120 during the subsequent removal of the sacrificial spacer 310. In some implementations, a material of the second spacer 320 includes one or more of silicon oxide, a low-k dielectric material, or an ultra-low-k dielectric material. The material of the second spacer 320 has a small dielectric constant, thereby further reducing parasitic capacitance between the gate structure 110 and the source/drain interconnecting layer.

The source/drain interconnecting layer 210 is in contact with the source/drain doped region 120 to realize an electrical connection between the source/drain doped region 120 and an external circuit or other interconnecting structures.

As an example, a material of the source/drain interconnecting layer 210 is copper. A relatively low resistivity of copper helps improve a delay of a back end of line RC and increase a processing speed of a chip, and also reduces a resistance of the source/drain interconnecting layer 210, thereby reducing power consumption accordingly. In other implementations, the material of the source/drain interconnecting layer may further be a conductive material such as tungsten or cobalt.

In some implementations, the step of forming the sidewall structure layer 300 and the source/drain interconnecting layer 210 includes:
forming a first sacrificial film 330 on the sidewall of the interconnecting trench 200 and suspended and spaced apart from the source/drain doped region 120, and a first spacer material layer 350 filling a gap between a bottom of the first sacrificial film 330 and the source/drain doped region 120 and extending onto a sidewall of the first sacrificial film 330, as shown in FIG. 11 to FIG. 13.

The first sacrificial film 330 is configured to form the sacrificial spacer with a subsequent second sacrificial film.

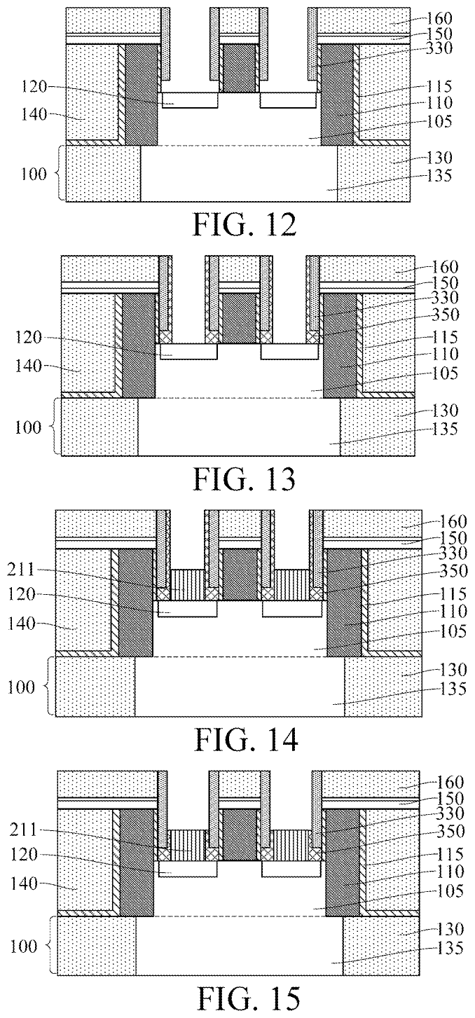

In some implementations, the step of forming the first sacrificial film 330 and the first spacer material layer 350 includes: forming a placeholder layer 335 on a bottom of the interconnecting trench 200, where atop surface of the placeholder layer 335 is lower than atop surface of the first dielectric layer 140, as shown in FIG. 11; forming the first sacrificial film 330 on the sidewall of the interconnecting trench 200 exposed from the placeholder layer 335; removing the placeholder layer 335, so that the bottom of the first sacrificial film 330 is suspended and spaced apart from the source/drain doped region 120, as shown in FIG. 12; and forming the first spacer material layer 350 filling a gap between the first sacrificial film 330 and the source/drain doped region 120 and extending onto the sidewall of the first sacrificial film 330, as shown in FIG. 13.

The placeholder layer 335 is configured to provide a process basis for the bottom of the first sacrificial film 330 to be suspended and spaced apart from the source/drain doped region 120.

In some implementations, a material of the placeholder layer 335 includes spin-on carbon (SOC), spin-on hard masks (SOH), or spin-on glass (SOG). As an example, the material of the placeholder layer 335 is the SOC. The SOC may be formed by spin coating, and the removal process is simple, which is beneficial to reduce the process difficulty of subsequently removing the placeholder layer 335.

A thickness of the placeholder layer 335 should be neither excessively small nor excessively large. If the thickness of the placeholder layer 335 is excessively small, after the placeholder layer 33 is subsequently removed, a gap between the bottom of the first sacrificial film 330 and the source/drain doped region 120 is excessively small, and the gap between the bottom of the first sacrificial film 330 and the source/drain doped region 120 is not easily filled with the first spacer material layer. If the thickness of the placeholder layer 335 is excessively large, after the placeholder layer 335 is subsequently removed, the gap between the bottom of the first sacrificial film 330 and the source/drain doped region 120 is relatively large, the first spacer material layer subsequently filling the gap between the bottom of the first sacrificial film 330 and the source/drain doped region 120 is excessively thick, and the volume of the air gap formed by removing the sacrificial spacer is excessively small, which easily leads to an insignificant reduction effect on the parasitic capacitance between the gate structure 110 and the source/drain interconnecting layer. In some implementations, the thickness of the placeholder layer 335 ranges from 0.5 nm to 2 nm.

In some implementations, the process of forming the placeholder layer 335 includes a spin coating process. The spin coating process has simple operation and strong filling ability, which is beneficial to improve formation quality of the placeholder layer 335 on the bottom of the interconnecting trench 200. In addition, surface flatness of a film layer formed by the spin coating process is relatively high, which is beneficial to improve flatness and height uniformity of the top surface of the placeholder layer 335.

More specifically, as an example, the step of forming the placeholder layer 335 includes: filling the interconnecting trench 200 with a placeholder material layer (not shown) by using the spin coating process; and removing a partial thickness of the placeholder material layer, where a remaining placeholder material layer is configured as the placeholder layer 335.

In some implementations, the partial thickness of the placeholder material layer is removed by using an anisotropic etching process (for example, the anisotropic dry etching process).

Specifically, the step of forming the first sacrificial film 330 includes: forming a first sacrificial material layer (not shown) on the bottom and the sidewall of the interconnecting trench 200 and on the second dielectric layer 160; and removing the first sacrificial material layer on the bottom of the interconnecting trench 200 and on the second dielectric layer 160 by using the anisotropic etching process.

In some implementations, the process of forming the first sacrificial material layer includes one or two of an atomic layer deposition process or a chemical vapor deposition process. In some implementations, the process of removing the placeholder layer 335 includes an ashing process. The ashing process has a relatively high selectivity, and the probability of generating by-products is low, which can help improve the process compatibility.

In some implementations, the step of forming the first spacer material layer 350 includes: forming a first spacer material film (not shown) on the bottom and the sidewall of the interconnecting trench 200 and on the second dielectric layer 160, where the first spacer material film further fills the gap between the bottom of the first sacrificial film 330 and the source/drain doped region 120; and removing the first spacer material film on the bottom of the interconnecting trench 200 and on the second dielectric layer 160 by using the anisotropic etching process, where the remaining first spacer material film filling the gap between the bottom of the first sacrificial film 330 and the source/drain doped region 120 and on the sidewall of the first sacrificial film 330 is configured as the first spacer material layer 350.

In some implementations, the process of forming the first spacer material film includes one or two of an atomic layer deposition process or a chemical vapor deposition process. As an example, the first spacer material film is formed by using the atomic layer deposition process. The atomic layer deposition process has a strong gap filling capability, which is beneficial to improve the filling quality of the first spacer material film between the bottom of the first sacrificial film 330 and the source/drain doped region 120.

In some implementations, in the step of forming the first sacrificial film 330 and the first spacer material layer 350, the process temperature ranges from 100° C. to 450° C., so as to prevent an excessively high process temperature from having an adverse effect on the semiconductor structure while improving the formation quality of the first sacrificial film 330 and the first spacer material layer 350.

As shown in FIG. 14, a bottom interconnecting layer 211 is formed in the interconnecting trench 200 in which the first sacrificial film 330 and the first spacer material layer 350 are formed. A top surface of the bottom interconnecting layer 211 is lower than the top surface of the first dielectric layer 140.

The bottom interconnecting layer 211 is configured to subsequently form a source/drain interconnecting layer with the top interconnecting layer. The top surface of the bottom interconnecting layer 211 is lower than the top surface of the first dielectric layer 140, so that the first spacer material layer 350 exposed from the bottom interconnecting layer 211 can be removed subsequently.

As shown in FIG. 15, the first spacer material layer 350 exposed from the bottom interconnecting layer 211 is removed, so as to expose a part of the sidewall of the first sacrificial film 330, so that a sidewall structure film is subsequently formed on the sidewall of the first sacrificial film 330 exposed from the bottom interconnecting layer 211.

Specifically, in some implementations, the first spacer material layer 350 exposed from the bottom interconnecting layer 211 is removed using an isotropic etching process.

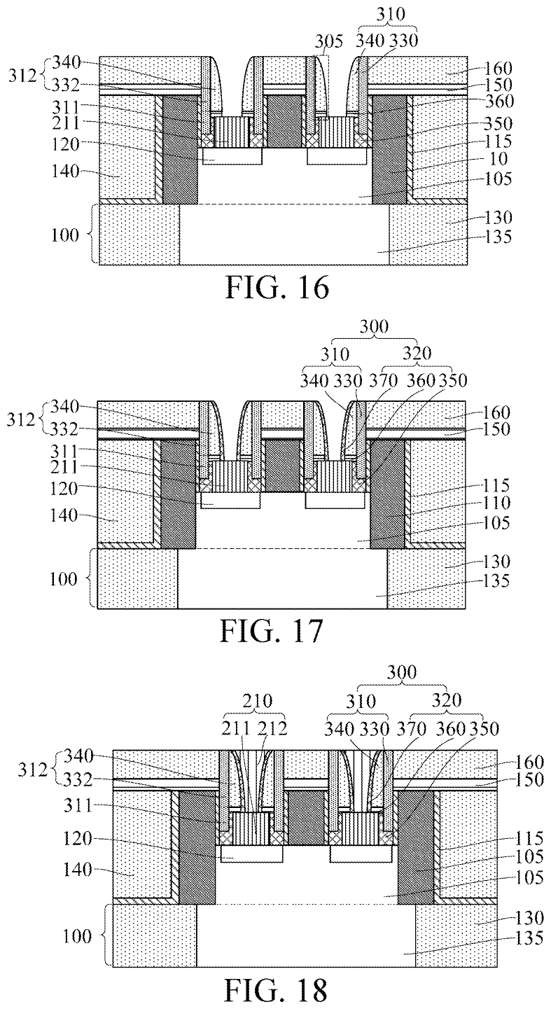

As shown in FIG. 16, a sidewall structure film 305 is formed on the sidewall of the first sacrificial film 330 exposed from the bottom interconnecting layer 211. The sidewall structure film 305 includes a second spacer material layer 360 on a part of the top surface of the bottom interconnecting layer 211 and on a top surface of the remaining first spacer material layer 350, and a second sacrificial film 340 on the second spacer material layer 35. The first sacrificial film 330 and the second sacrificial film 340 are configured to form the sacrificial spacer 310.

The second spacer material layer 360 is configured to form a second spacer with the first spacer material layer 350 and a subsequently formed third spacer material layer.

In some implementations, the step of forming the sidewall structure film 305 includes: forming a second spacer material layer 360 on the bottom of the interconnecting trench 200; forming the second sacrificial film 340 on the sidewall of the first sacrificial film 330, where the second sacrificial film 340 covers a part of a top of the second spacer material layer 360; and removing the second spacer material layer 360 exposed from the second sacrificial film 340.

The step of forming the second spacer material layer 360 on the bottom of the interconnecting trench 200 includes: forming a first spacer film (not shown) on the bottom and the sidewall of the interconnecting trench 200, where a thickness of the first spacer film on the bottom of the interconnecting trench 200 is greater than a thickness of the first spacer film on the sidewall of the interconnecting trench 200, and removing the first spacer film on the sidewall of the interconnecting trench 200 by using the isotropic etching process, where the remaining first spacer film on the bottom of the interconnecting trench 200 is configured as the second spacer material layer 360.

In some implementations, the process of forming the first spacer film includes one or two of an atomic layer deposition process or a chemical vapor deposition process. In the step of forming the first spacer film, by controlling directionality of plasma, the thickness of the first spacer film deposited on the bottom of the interconnecting trench 200 is greater than the thickness of the first spacer film deposited on the sidewall of the interconnecting trench 200.

In some implementations, the step of forming the second sacrificial film 340 on the sidewall of the first sacrificial film 330 includes: forming a second sacrificial material layer (not shown) on the bottom and the sidewall of the interconnecting trench 200 and on the second dielectric layer 160; and removing the second sacrificial material layer on the bottom of the interconnecting trench 200 and on the second dielectric layer 160 using the anisotropic etching process, where the remaining second sacrificial material layer on the sidewall of the interconnecting trench 200 is configured as the second sacrificial film 340.

In some implementations, the process of forming the second sacrificial material layer includes one or two of an atomic layer deposition process or a chemical vapor deposition process.

In some implementations, after removing the second sacrificial material layer on the bottom of the interconnecting trench 200 and on the second dielectric layer 160 by using the anisotropic etching process, the second spacer material layer 360 exposed from the second sacrificial film 340 continues to be removed by using the anisotropic etching process.

In some implementations, a part of the first sacrificial film 330 lower than the top surface of the second spacer material layer 360 is configured as the first sacrificial portion 311, and a part of the first sacrificial film 330 higher than the top surface of the second spacer material layer 360 is configured to form the second sacrificial portion 312 with the second sacrificial film 340.

As shown in FIG. 17, a third spacer material layer 370 is formed on the sidewall of the sidewall structure film 305. The third spacer material layer 370, the first spacer material layer 350, and the second spacer material layer 360 are configured to form the second spacer 320.

In some implementations, the first spacer material layer 350, the second spacer material layer 360, and the third spacer material layer 370 are made of a same material, which can help improve process compatibility. In other implementations, the first spacer material layer, the second spacer material layer, and the third spacer material layer made further be made of different materials.

In some implementations, the step of forming the third spacer material layer 370 includes: forming a second spacer film (not shown) on the sidewall and the top of the spacer structure film 305 and on the bottom of the interconnecting trench 200; and removing the second spacer film on the top of the spacer structure film 305 and on the bottom of the interconnecting trench 200, where the remaining second spacer film on the sidewall of the spacer structure film 305 is configured as the third spacer material layer 370.

In some implementations, the process of forming the second spacer film includes one or two of an atomic layer deposition process or a chemical vapor deposition process. In some implementations, the second spacer film on the top of the spacer structure film 305 and on the bottom of the interconnecting trench 200 is removed by using the anisotropic etching process.

As shown in FIG. 18, after the third spacer material layer 370 is formed, a top interconnecting layer 212 filling the interconnecting trench 200 is formed on the bottom interconnecting layer 211. The top interconnecting layer 212 and the bottom interconnecting layer 211 are configured to form a source/drain interconnecting layer 210.

It should be noted that, in some implementations, in the steps of forming the first sacrificial film, the first spacer material layer, the second sacrificial film, the second spacer material layer, and the third spacer material layer, the process temperature ranges from 100° C. to 450° C., so as to prevent an excessive temperature from causing damage to the semiconductor structure while ensuring the forming quality of the first sacrificial film, the first spacer material layer, the second sacrificial film, the second spacer material layer, and the third spacer material layer.

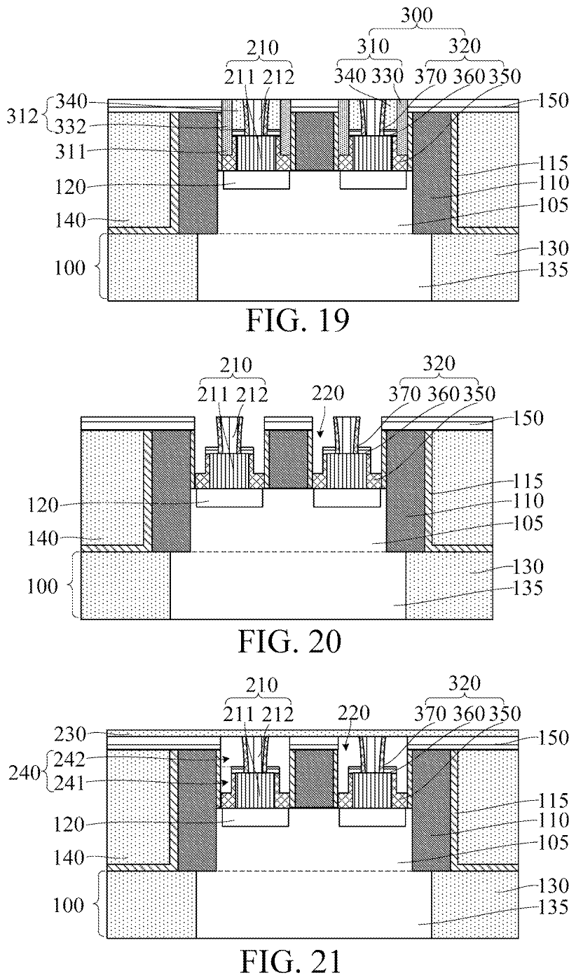

Referring to FIG. 19, in some implementations, after forming the sidewall structure layer 300 and the source/drain interconnecting layer 210, the method for forming a semiconductor structure further includes planarizing the source/drain interconnecting layer 210 and the second dielectric layer 140 by using a top surface of the planarization stop layer 150 as a stop position.

The source/drain interconnecting layer 210 and the second dielectric layer 140 are planarized by using the top surface of the planarization stop layer 150 as the stop position, thereby improving height uniformity and flatness of the top surface of the source/drain interconnecting layer 210 after the planarization.

In addition, in the field of semiconductors, in the step of forming the second sacrificial portion 340, the second sacrificial portion 340 closer to the base 100 has a larger width. In the step of planarizing the source/drain interconnecting layer 210 and the second dielectric layer 140, the sidewall structure layer 300 is further planarized, so as to remove a partial height of the sidewall structure layer 300, which can help increase an exposed area of the top surface of the sacrificial spacer 310, thereby reducing the process difficulty of removing the sacrificial spacer 310 and increasing the process window for removing the sacrificial spacer 310.

Specifically, in some implementations, the planarization is performed using a chemical-mechanical planarization (CMP) process.

Referring to FIG. 20, the sacrificial spacer 310 is removed to form an air gap 220 defined by the second spacer 320[sy1] and the first spacer. A sealing layer sealing the air gap 220 is subsequently formed, and the sealing layer, the first spacer, and the sidewall structure layer define the air spacer.

In some implementations, the exposed area of the top of the sacrificial spacer 310 is relatively large. In the step of removing the sacrificial spacer 310 to form the air gap 220, the process difficulty of removing the sacrificial spacer 310 can be reduced, and the process window for forming the air gap 220 can be increased.

In addition, in the subsequent formation of the sealing layer sealing the top of the air gap 220, after the sealing layer, the first spacer, and the second spacer 320 define the air spacer, the width of the part of the air spacer close to the top is larger, which is beneficial to increase a volume of the air spacer, and further beneficial to increase the proportion of the air spacer between the gate structure 110 and the source/drain interconnecting layer 210. Accordingly, the parasitic capacitance between the gate structure 110 and the source/drain interconnecting layer 210 is further reduced, and the performance of the semiconductor structure is optimized.

In addition, compared with the case that the sacrificial spacer is arranged on all sidewalls of the gate structure, in some implementations, the sacrificial spacer 310 is only arranged on the sidewall of the interconnecting trench 200, which is beneficial to reduce the difficulty of removing the sacrificial spacer 310 and reduce the probability that the process of removing the sacrificial spacer 310 causes adverse effects on other film layers.

In addition, in some implementations, before a source/drain plug in contact with the source/drain interconnecting layer 210 and a gate plug in contact with the gate structure 110 are formed, the sacrificial spacer 310 is removed, and the height of the sacrificial spacer 310 is correspondingly reduced, which is beneficial to reduce a depth-to-width ratio of the air gap 220 accordingly, and further beneficial to reduce the process difficulty of forming the air gap 220 and increase the process window for forming the air gap 220.

In some implementations, the sacrificial spacer 310 is removed using the isotropic etching process. The isotropic etching process has an isotropic etching property and a strong gap etching capability, which is beneficial to remove and clean the sacrificial spacer 310 and reduce the probability of the sacrificial sidewall 310 remaining. As an example, the process of removing the sacrificial spacer 310 includes a remote plasma etching process or a wet etching process.

Referring to FIG. 21, a sealing layer 230 sealing the top of the air gap 220 is formed, so that the sealing layer 230, the first spacer, and the second spacer 320 define an air spacer 240.

The air spacer 240 is arranged between the source/drain interconnecting layer 210 and the gate structure 110, and a dielectric constant of the air spacer 240 is lower than a dielectric constant of a common dielectric material in the field of semiconductors, which is beneficial to reduce the parasitic capacitance between the gate structure 110 and the source/drain interconnecting layer 210.

In some implementations, the width of the part of the air spacer 240 close to the top is larger, which is beneficial to increase a volume of the air spacer 240, and further beneficial to increase a proportion of the air spacer 240 between the gate structure 110 and the source/drain interconnecting layer 210. Accordingly, the parasitic capacitance between the gate structure 110 and the source/drain interconnecting layer 210 is further reduced, and the performance of the semiconductor structure is optimized.

In some implementations, the air spacer 240 includes a first portion 241 and a second portion 242 on the first portion 241. Along a direction perpendicular to the sidewall of the first spacer, a width of the second portion 242 is greater than a width of the first portion 241.

In some implementations, a material of the sealing layer 230 includes one or more of silicon oxide, silicon nitride, a low-k dielectric material, or an ultra-low-k dielectric material. In some implementations, the sealing layer 230 is further formed on the planarization stop layer 150.

In some implementations, the process of forming the sealing layer 230 includes one or two of a chemical vapor deposition process or a plasma enhanced chemical vapor deposition process. As an example, the sealing layer 230 is formed by using the chemical vapor deposition process. The gap filling capability of the chemical vapor deposition process is relatively weak, which can facilitate contacting at a top corner of the air gap 220 to seal the top of the air gap 220, and the chemical vapor deposition process has high process compatibility and low process costs.

Although the present disclosure is described above, the present disclosure is not limited thereto. A person skilled in the art can make various changes and modifications without departing from the spirit and the scope of the present disclosure. Therefore, the protection scope of the present disclosure should be subject to the scope defined by the claims.

What is claimed is:

1. A semiconductor structure, comprising:
a base;
a plurality of gate structures, separately arranged on the base;
a first spacer, arranged on a sidewall of each of the gate structures of the plurality of gate structures;
a source/drain doped region, arranged within the base on two sides of the gate structures of the plurality of gate structures;
a first dielectric layer, arranged on the gate structures of the plurality of gate structures and on the base and the source/drain doped region that are located on a side of the first spacer;
a source/drain interconnecting layer, extending through the first dielectric layer on a top of the source/drain doped region, wherein a sidewall of the source/drain interconnecting layer is spaced apart from a sidewall of the first spacer;
an air gap, arranged between the first spacer and the source/drain interconnecting layer;
a second spacer, arranged on a bottom of the air gap and on the source/drain interconnecting layer exposed from the air gap; and
a sealing layer, sealing a top of the air gap, wherein the sealing layer, the first spacer, and the second spacer form an air spacer, and along a direction perpendicular to the sidewall of the first spacer, a width of a part of the air spacer away from the base is greater than a width of a part of the air spacer close to the base.

2. The semiconductor structure according to claim 1, wherein:
the source/drain interconnecting layer comprises a bottom interconnecting layer and a top interconnecting layer on the bottom interconnecting layer, and
along a direction perpendicular to an extending direction of the gate structure, a sidewall of the top interconnecting layer is retracted relative to a sidewall of the bottom interconnecting layer on a same side.

3. The semiconductor structure according to claim 1, wherein:
the air spacer comprises a first portion and a second portion on the first portion, and
along the direction perpendicular to the sidewall of the first spacer, a width of the second portion is greater than a width of the first portion.

4. The semiconductor structure according to claim 3, wherein the second spacer comprises:
a first spacer material layer, arranged on a bottom of the first portion and on the bottom interconnecting layer exposed from the first portion;
a second spacer material layer, arranged on a top surface of the bottom interconnecting layer exposed from the second portion and covering a top of the first spacer material layer; and
a third spacer material layer, arranged on a sidewall of the top interconnecting layer exposed from the second portion and connected to the second spacer material layer; or
the second spacer is integrally formed.

5. The semiconductor structure according to claim 4, wherein a material of the first spacer material layer is the same as a material of the second spacer material layer and a material of the third spacer material layer.

6. The semiconductor structure according to claim 1, wherein:
the sealing layer is arranged on the first dielectric layer and the gate structure and seals the top of the air gap, and
the semiconductor structure further comprises a planarization stop layer arranged between the first dielectric layer and the sealing layer and between a top of the gate structure and the sealing layer.

7. The semiconductor structure according to claim 1, wherein:
a material of the first spacer comprises at least one of silicon oxide, a low-k dielectric material, or an ultra-low-k dielectric material;
a material of the sealing layer comprises at least one of silicon oxide, silicon nitride, a low-k dielectric material, or an ultra-low-k dielectric material; and
a material of the second spacer comprises at least one of silicon oxide, silicon nitride, a low-k dielectric material, or an ultra-low-k dielectric material.

8. The semiconductor structure according to claim 1, wherein a thickness of the second spacer on the bottom of the air gap ranges from 0.5 nm to 2 nm.

9. A method for forming a semiconductor structure, comprising:
providing a base, wherein a plurality of separate gate structures is formed on the base, a first spacer is formed on a sidewall of each gate structure of the plurality of gate structures, a source/drain doped region is formed in the base on two sides of the gate structures of the plurality of gate structures, and a first dielectric layer is formed on the gate structure and on the base and the source/drain doped region that are located on a side of the first spacer;
forming an interconnecting trench extending through the first dielectric layer on a top of the source/drain doped region, wherein a sidewall of the first spacer and the source/drain doped region are exposed from the interconnecting trench;
forming a sidewall structure layer on a sidewall of the interconnecting trench, and forming a source/drain interconnecting layer on a sidewall of the sidewall structure layer, filling the interconnecting trench, and in contact with the source/drain doped region, wherein the sidewall structure layer comprises:
a sacrificial spacer, arranged on the sidewall of the first spacer and suspended and spaced apart from the source/drain doped region, wherein along a direction perpendicular to the sidewall of the first spacer, a width of a part of the sacrificial spacer away from the base is greater than a width of a part of the sacrificial spacer close to the base; and
a second spacer, filling a gap between a bottom of the sacrificial spacer and the source/drain doped region and arranged between the sacrificial spacer and the source/drain interconnecting layer;
removing the sacrificial spacer to form an air gap defined by the second spacer and the first spacer; and
forming a sealing layer sealing a top of the air gap, so that the sealing layer, the first spacer, and the second spacer form an air spacer.

10. The method for forming a semiconductor structure according to claim 9, wherein the step of forming the sidewall structure layer and the source/drain interconnecting layer comprises:
forming a first sacrificial film on the sidewall of the interconnecting trench and suspended and spaced apart from the source/drain doped region, and forming a first spacer material layer filling a gap between a bottom of the first sacrificial film and the source/drain doped region and extending onto a sidewall of the first sacrificial film;
forming a bottom interconnecting layer in the interconnecting trench in which the first sacrificial film and the first spacer material layer are formed, wherein a top surface of the bottom interconnecting layer is lower than a top surface of the first dielectric layer;
removing the first spacer material layer exposed from the bottom interconnecting layer;
forming a sidewall structure film on the sidewall of the first sacrificial film exposed from the bottom interconnecting layer, wherein the sidewall structure film comprises a second spacer material layer on a part of the top surface of the bottom interconnecting layer and a top surface of the remaining first spacer material layer, and forming a second sacrificial film on the second spacer material layer, wherein the first sacrificial film and the second sacrificial film are configured to form the sacrificial spacer;
forming a third spacer material layer on a sidewall of the sidewall structure film, wherein the third spacer material layer, the first spacer material layer, and the second spacer material layer are configured to form the second spacer; and
forming, on the bottom interconnecting layer, a top interconnecting layer filling the interconnecting trench after forming the third spacer material layer, wherein the top interconnecting layer and the bottom interconnecting layer are configured to form the source/drain interconnecting layer.

11. The method for forming a semiconductor structure according to claim 10, wherein the step of forming the first sacrificial film and the first spacer material layer comprises:
forming a placeholder layer on a bottom of the interconnecting trench, wherein a top surface of the placeholder layer is lower than a top surface of the first dielectric layer;
forming the first sacrificial film on the sidewall of the interconnecting trench exposed from the placeholder layer;
removing the placeholder layer, so that the bottom of the first sacrificial film is suspended and spaced apart from the source/drain doped region; and
forming the first spacer material layer filling a gap between the first sacrificial film and the source/drain doped region and extending onto the sidewall of the first sacrificial film.

12. The method for forming a semiconductor structure according to claim 11, wherein in the step of forming the placeholder layer, a material of the placeholder layer is spin-on carbon, spin-on hard masks, or spin-on glass.

13. The method for forming a semiconductor structure according to claim 11, wherein in the step of forming the placeholder layer, a thickness of the placeholder layer ranges from 0.5 nm to 2 nm.

14. The method for forming a semiconductor structure according to claim 11, wherein the step of forming the sidewall structure film comprises:
forming a second spacer material layer on the bottom of the interconnecting trench;
forming the second sacrificial film on the sidewall of the first sacrificial film, wherein the second sacrificial film covers a part of a top of the second spacer material layer; and
removing the second spacer material layer exposed from the second sacrificial film.

15. The method for forming a semiconductor structure according to claim 14, wherein the step of forming the second spacer material layer on the bottom of the interconnecting trench comprises:
forming a first spacer film on the bottom and the sidewall of the interconnecting trench, wherein a thickness of the first spacer film on the bottom of the interconnecting trench is greater than a thickness of the first spacer film on the sidewall of the interconnecting trench; and
removing the first spacer film on the sidewall of the interconnecting trench using an isotropic etching process, wherein the remaining first spacer film on the bottom of the interconnecting trench is configured as the second spacer material layer.

16. The method for forming a semiconductor structure according to claim 9, wherein:
after providing the base and before forming the interconnecting trench, the method for forming a semiconductor structure further comprises:
forming a planarization stop layer on the first dielectric layer, wherein the planarization stop layer covers a top of the gate structure; and
forming a second dielectric layer on the planarization stop layer;
in the step of forming the interconnecting trench, the interconnecting trench extends through the first dielectric layer, the planarization stop layer, and the second dielectric layer on the top of the source/drain doped region; and
after forming the sidewall structure layer and the source/drain interconnecting layer and before removing the sacrificial spacer, the method for forming a semiconductor structure further comprises: planarizing the source/drain interconnecting layer and the second dielectric layer by using a top surface of the planarization stop layer as a stop position.

17. The method for forming a semiconductor structure according to claim 10, wherein in the steps of forming the first sacrificial film, the first spacer material layer, the second sacrificial film, the second spacer material layer, and the third spacer material layer, a process temperature ranges from 100° C. to 450° C.

18. The method for forming a semiconductor structure according to claim 9, wherein a process of forming the sealing layer comprises one or two of a chemical vapor deposition process or a plasma enhanced chemical vapor deposition process.

19. The method for forming a semiconductor structure according to claim 9, wherein a process of removing the sacrificial spacer comprises a remote plasma etching process or a wet etching process.

20. The method for forming a semiconductor structure according to claim 9, wherein a material of the sacrificial spacer comprises one or more of amorphous silicon, silicon oxycarbide, silicon oxide, silicon nitride, silicon carbide, boron nitride, aluminum oxide, aluminum nitride, or silicon oxynitride.
